(19) United States
(12) Patent Application Publication
(10) Pub. No.: US 2020/0278611 A1
(43) Pub. Date: Sep. 3, 2020

(54) A METHOD OF PREPARING A PLANAR OPTICAL WAVEGUIDE ASSEMBLY

(71) Applicant: Dow Silicones Corporation, Midland, MI (US)

(72) Inventors: Kai Su, Midland, MI (US); Karmen Asch, Beaverton, MI (US); Brandon Swatowski, Sanford, MI (US); Jon Vierling Degroot, JR., Midland, MI (US)

(21) Appl. No.: 16/606,945

(22) PCT Filed: Jun. 15, 2018
(86) PCT No.: PCT/US2018/037681

§ 371 Date: Oct. 21, 2019

Related U.S. Application Data
(60) Provisional application No. 62/538,427, filed on Jul. 28, 2017.

(51) Int. Cl. G03F 7/075; G02B 1/04

(52) U.S. Cl. CPC G03F 7/0757; G03F 7/20; G02B 1/048; G02B 1/046

(57) ABSTRACT

This invention relates to a method of preparing a planar optical waveguide assembly comprising the steps of: (i) applying a curable silicone composition to a surface of a substrate to form a film; (ii) exposing the product of step (i) to ultraviolet light to form a lower clad layer; (iii) applying a photo sensitive composition on top of the lower clad layer to form a core layer on top of the lower clad layer, wherein the photo sensitive composition comprises: (A) a siloxane resin composition comprising 0 to 95 mole present of R¹SiO_{3/2} siloxane units, 0 to 95 mole percent of R²SiO_{3/2} siloxane units, and 1 to 99.9 mole percent of (R³O)_{b}SiO_{(4-b)/2} siloxane units wherein R¹ is hydrogen, an alkyl group containing 1 to 20 carbon atoms, an aromatic group containing 1 to 20 carbon atoms, or an epoxy functional group, R² is a fluoroalkyl group containing 1 to 20 carbon atoms, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 5 mole percent of the total siloxane units in the resin composition; (B) a photo acid generator (PAG); and (C) an organic solvent; (iv) exposing the product of step (iii) to ultraviolet light through a mask to selectively irradiate the core layer to create both exposed and unexposed regions to form a patterned waveguide structure; (v) heating the patterned waveguide structure of step (iv); (vi) applying a developing solvent to the product of step (v); (vii) applying a curable silicone composition onto the top layer of the product of step (vi) wherein the curable silicone composition has a lower refractive index than the curable silicone composition of step (i); (viii) exposing the product of step (vii) to ultraviolet light; (viv) heating the product of step (viii) to form a planar optical waveguide assembly.

### CROSS-REFERENCE TO RELATED APPLICATIONS

This application claims the benefit of U.S. Provisional Patent Application Ser. No. 62/538,427 filed on 28 Jul. 2017 under 35 U.S.C. § 119 (e). U.S. Provisional Patent Application Ser. No. 62/538,427 is hereby incorporated by reference.

### BACKGROUND OF THE INVENTION

This invention is related to a new UV curable compositions that can be used to fabricate waveguide with low optical loss via lithographic process. The optical loss of polymeric materials at wavelength used for telecommunication (1310 nm) mainly results from the overtone from stretching of saturate CH and OH bonds that are present in the polymeric materials. Substitution of CH bond with CF bond and the use of aromatic substituents have been widely utilized to reduce optical loss. Although effective, saturated CH bond that comes with the functionality used for UV cure, such as epoxy and acrylate are always present. In this invention, we present the use of silsesquioxanes that contain a combination of fluoro, phenyl and tert-butoxy groups that can be photo cured and converted to materials that have minimum saturate CH bond.

Tert-butoxy group connected to silicone has been demonstrated underwent elimination of isobutene in a process that was catalyzed by acid. However, the use of photo acid generator with a tert-butoxy containing silsesquioxane for fabrication of polymer waveguide has not been reported. UV radiation of a material that contains photo acid generator (PAG) can lead to decomposition of PAG and release of a super acid. The acid then catalyze the decomposition of the tert-butoxy group to produce isobutene and the formation of silanol group. Condensation of silanol or silanol with residual methoxy lead to curing of the materials. In these resin compositions, tert-butoxy is the only functional group in addition to the ethylene linkage in the fluoro side chain (for example when R is CH₂CH₂(CF₂)₅CF₃). As a result, elimination of tert-butoxy group can reduce the saturate CH bond in the material and therefore lower the optical loss at 1310 nm.

### BRIEF SUMMARY OF THE INVENTION

This invention relates to a method of preparing a planar optical waveguide assembly comprising the steps of:

(i) applying a curable silicone composition to a surface of a substrate to form a film;

(ii) exposing the product of step (i) to ultraviolet light to form a lower clad layer;

(iii) applying a photo sensitive composition on top of the lower clad layer to form a core layer on top of the lower clad layer, wherein the photo sensitive composition comprises:
(A) a siloxane resin composition comprising 0 to 95 mole present of R¹SiO_{3/2} siloxane units, 0 to 95 mole percent of R²SiO_{3/2} siloxane units, and 1 to 99.9 mole percent of (R³O)_{b}SiO_{(4-b)/2} siloxane units wherein R¹ is hydrogen, an alkyl group containing 1 to 20 carbon atoms, an aromatic group containing 1 to 20 carbon atoms, or an epoxy functional group, R² is a fluoroalkyl group containing 1 to 20 carbon atoms, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 5 mole percent of the total siloxane units in the resin composition;
(B) a photo acid generator (PAG); and
(C) an organic solvent;

(iv) exposing the product of step (iii) to ultraviolet light through a mask to selectively irradiate the core layer to create both exposed and unexposed regions to form a patterned waveguide structure;

(v) heating the patterned waveguide structure of step (iv);

(vi) applying a developing solvent to the product of step (v);

(vii) applying a curable silicone composition onto the top layer of the product of step (vi) wherein the curable silicone composition has a lower refractive index than the curable silicone composition of step (i);

(viii) exposing the product of step (vii) to ultraviolet light;

(viv) heating the product of step (viii) to form a planar optical waveguide assembly.

The method of the present invention is scaleable to a high throughput manufacturing process. Importantly, the method allows simultaneous fabrication of multiple waveguides on a single substrate. Additionally, the method employs conventional wafer fabrication techniques (e.g., coating, exposing, developing, curing) and equipment. Furthermore, the method uses a photopatternable silicone composition, thereby eliminating additional process steps, for example, applying a photoresist and etching, associated with use of a non-photopatternable polymer composition. Finally, the process of the instant invention has high resolution, meaning that the process transfers images from a photomask to the silicone film with good retention of critical dimensions.

The planar optical waveguide assembly of the present invention exhibits good thermal stability over a wide range of temperatures and good environmental resistance, particularly moisture resistance. Also, the waveguide assembly exhibits low birefringence and low transmission loss.

The optical waveguide assembly of the present invention can be used to fabricate components of optical integrated circuits, such as attenuators, switches, splitters, routers, filters, and gratings.

These and other features, aspects, and advantages of the present invention will become better understood with reference to the following description, appended claims, and accompanying drawing.

### BRIEF DESCRIPTION OF THE DRAWINGS

FIG. 1 shows the insertion loss of waveguide straights at various lengths @ 1310 nm.

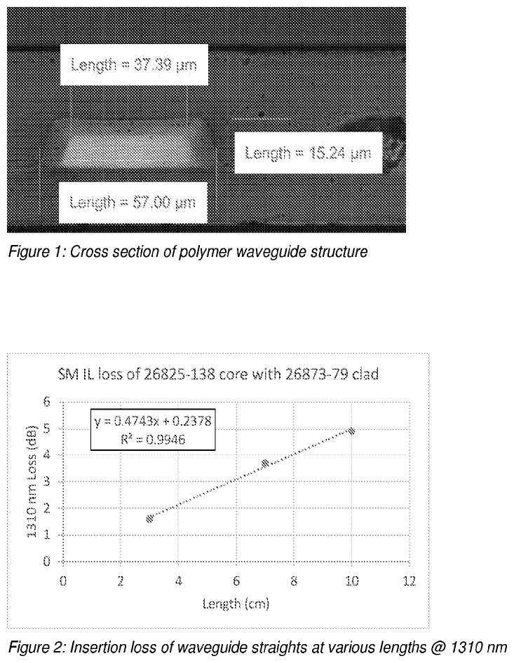

### DETAILED DESCRIPTION

As used herein, the term “planar optical waveguide assembly” refers to a waveguide assembly containing at least one core having a rectangular cross section. Also, as used herein, the “refractive index” of a substance is defined as the ratio of the velocity of light in a vacuum to the velocity of light in the substance at 25° C. for light having a wavelength of 589 nm.

Step (i) in the method of this invention comprises applying a curable silicone composition to a surface of a substrate to form a film. The curable polymer composition can be any polymer composition that cures in step (ii) to form a lower clad layer having a refractive index less than the refractive index of the silicone core. The cure mechanism of the polymer composition is not limited. Examples of curable polymer compositions include curable silicone compositions, such as radiation curable silicone compositions and hydrosilylation-curable silicone compositions.

The curable silicone coating can also be any of the radiation curable coating compositions known in the art such as UV (ultraviolet) or EB (electron beam) curable compositions. The radiation curable coating composition can comprise: (I) an organosilicon compound having at least two groups selected from the group consisting of epoxy groups, vinyl ether groups, acrylate groups, or acrylamide groups; and (II) an initiator. The epoxy group can be any functional group in which an oxygen atom, the epoxy substituent, is directly attached to two adjacent carbon atoms of a carbon chain or ring system. Examples of epoxy functional groups include, but are not limited to, 2,3-epoxypropyl, 3,4-epoxybutyl, 4,5-epoxypentyl, 2-glycidoxyethyl, 3-glycidoxypropyl, 4-glycidoxybutyl, 2-(3,4-epoxycylohexyl)ethyl, 3-(3,4-epoxycylohexyl)propyl, 2-(3,4-epoxy-3-methylcylohexyl)-2-methylethyl, 2-(2,3-epoxycylopentyl)ethyl, and 3-(2,3-epoxycylopentyl)propyl.

Compound (I) is typically an epoxy-containing organopolysiloxane polymer or epoxy-containing organopolysilxoane resin. Suitable epoxy functional organopolysiloxane polymers have the general formula AR₂SiO(R₂SiO)ₓ(RESiO)ySiR₂A wherein R is a monovalent hydrocarbon radical having from 1 to 20 carbon atoms exemplified by an alkyl group such as methyl, E is an epoxy group as described above or having the formula —R⁴E wherein R₄ is a divalent hydrocarbon group having from 1 to 20 carbon atoms such as methylene, ethylene, propylene, butylene, phenylene, trimethylene, 2-methyltrimethylene, pentamethylene, hexamethylene, 3-ethylhexamethylene, octamethlyene, cyclohexylene, phenylene, and benzylene, A denotes R or E, x has a value of 0 to 500, y has a value of 0 to 200 with the proviso that there are at least two epoxy groups per compound. Preparation of such compounds is well known in the organosilicon art and needs no extensive delineation herein.

The epoxy-functional organopolysiloxane resin is represented by the average siloxane unit formula:

(R⁴R⁵R⁶SiO_{1/2})ₐ(R⁷R⁸SiO_{2/2})_{b}(R⁹SiO_{3/2})_{c}(SiO_{4/2})_{d}

wherein R⁴, R⁵, R⁶, R⁷, R⁸, and R⁹ are organic groups independently selected from C₁₋₆ monovalent aliphatic hydrocarbon groups, C₆₋₁₀ monovalent aromatic hydrocarbon groups, and epoxy-substituted functional groups as described above, 0≤a<0.4, 0<b<0.5, 0<c<1, 0≤d<0.4, 0.1≤b/c≤0.3, a+b+c+d=1, the resin has a number-average molecular weight of at least about 2000, at least about 15 mol % of the organic groups are C₆ to C₁₀ monovalent aromatic hydrocarbon groups, and about 2 to about 50 mol % of siloxane units per molecule have epoxy-substituted organic groups. Due to the epoxy groups it contains, the resin can quickly cure upon irradiation with active energy rays, such as UV rays, electron beams, or ionizing radiation, in the presence of (C) a cationic photoinitiator. Optionally, a photosensitizes can also be present in the composition. When the composition is in contact with a substrate (for example, a silicon substrate), irradiating it with active energy rays, such as UV rays, electron beams or ionizing radiation, causes the composition to cure. The cured composition can be firmly adhered to the substrate.

In the epoxy-functional organopolysiloxane resin represented by the average siloxane unit formula above, the (R⁷R⁸SiO_{2/2}) units and (R⁹SiO_{3/2}) units are present, whereas the (R⁴R⁵R⁶SiO_{1/2}) and (SiO_{4/2}) units are optional constituent units. Thus, there can be epoxy-functional organopolysiloxane resins including the following units:

(R⁷R⁸SiO_{2/2})_{b}(R⁹SiO_{3/2})_{c};

(R⁴R⁵R⁶SiO_{1/2})ₐ(R⁷R⁸SiO_{2/2})_{b}(R⁹SiO_{3/2})_{c};

(R⁷R⁸SiO_{2/2})_{b}(R⁹SiO_{3/2})_{c}(SiO_{4/2})_{d}; or

(R⁴R⁵R⁶SiO_{1/2})ₐ(R⁷R⁸SiO_{2/2})_{b}(R⁹SiO_{3/2})_{c}(SiO_{4/2})_{d}.

In descriptions of average unit formulas above, the subscripts a, b, c, and d are mole fractions. The subscript a is 0≤a<0.4 because the molecular weight of the epoxy-containing organopolysiloxane resin drops when there are too many (R⁴R⁵R⁶SiO_{1/2}) units, and, when (SiO_{4/2}) units are introduced, the hardness of the cured product of the epoxy-functional organopolysiloxane resin is markedly increased and the product can be easily rendered brittle. For this reason, the subscript d is 0≤d<0.4, 0≤d<0.2, or d=0. In addition, the molar ratio b/c of the (R⁷R⁸SiO_{2/2}) units and (R⁹SiO_{3/2}) units can be not less than about 0.01 and not more than about 0.3. In some examples, deviation from this range in the manufacture of the epoxy-functional organopolysiloxane resin can result in generation of insoluble side products, in making the product more prone to cracking due to decreased toughness, or in a decrease in the strength and elasticity of the product and making it more prone to scratching. In some examples, the range molar ratio b/c is not less than about 0.01 and not more than about 0.25, or not less than about 0.02 and not more than about 0.25. The epoxy-functional organopolysiloxane resin contains the (R⁷R⁸SiO_{2/2}) units and (R⁹SiO_{3/2}) units, and its molecular structure is in most cases a network structure or a three-dimensional structure because the molar ratio of b/c is not less than about 0.01 and not more than about 0.3. The silicon-bonded C₁₋₆ monovalent aliphatic hydrocarbon groups in component (A) are exemplified by methyl, ethyl, propyl, butyl, hexyl, and other monovalent saturated aliphatic hydrocarbon groups, and by vinyl, allyl, hexenyl, and other monovalent unsaturated aliphatic hydrocarbon groups. In addition, the silicon-bonded C₆₋₁₀ monovalent aromatic hydrocarbon groups are exemplified by phenyl, tolyl, xylyl, and naphthyl.

The siloxane units having epoxy-functional groups constitute about 2 mol % to about 50 mol %, about 10 mol % to about 40 mol %, or about 15 mol % to about 40 mol % of all the siloxane units. If there is less than 2 mol % of such siloxane units, the density of cross-linking during curing can be low, which can make it difficult to obtain hardness that is sufficient for an optical transmission component. On the other hand, an amount exceeding 50 mol % can be unsuitable because it can bring about a decrease in the optical transmittance and heat resistance of the cured product. In the epoxy-functional monovalent hydrocarbon groups, the epoxy groups can be bonded to silicon atoms through alkylene groups, such that these epoxy groups are not directly bonded to the silicon atoms. The epoxy-functional organopolysiloxane resin can be produced by well-known conventional manufacturing methods, such as, for example, the methods disclosed in JP6298940. Component (I) can include a combination of two or more kinds of such epoxy-functional organopolysiloxane resins with different content and type of the epoxy-containing organic groups and monovalent hydrocarbon groups or with different molecular weights.

It is preferred that from 30 to 99.5 weight percent of the radiation curable organosilicon compound (I) be used in the radiation curable coating compositions of the invention, and it is highly preferred that from 97 to 99 weight percent of this compound be employed, said weight percent being based on the total weight of the radiation curable silicone coating composition. Component (I) can also be diluted with other smaller compounds that contain epoxy functionality to reduce viscosity of the formulation.

Compounds suitable as the initiator (II) include photoinitiators and sensitizers. Sensitizers have been described in great detail in the art in numerous publications and include materials such as the well known material benzophenone. Suitable initiators include onium salts, certain nitrobenzyl sulfonate esters, diaryliodonium salts of sulfonic acids, triarylsulfonium salts of sulfonic acids, diaryliodonium salts of boronic acids, and triarylsulfonium salts of boronic acids. Bis-diaryl iodonium salts, such as bis(dodecyl phenyl) iodonium hexafluoroarsenate and bis(dodecylphenyl) iodonium hexafluoroantimonate, and dialkylphenyl iodonium hexafluoroantimonate are suitable initiators. Diaryliodonium salts of sulfonic acids, triarylsulfonium salts of sulfonic acids, diaryliodonium salts of boronic acids, and triarylsulfonium salts of boronic acids are also suitable as initiator (ii) in the radiation curable silicone coatings. Preferred diaryioadonium salts of sulfonic acid are selected from diaryliodonium salts of perfluoroalkylsulfonic acids and diaryliodonium salts of aryl sulfonic acids. Preferred diaryliodonium salts of perfluoroalkylsulfonic acids include diaryliodonium salts of perfluorobutanesulfonic acid, diaryliodonium salts of perfluoroethanesulfonic acid, diaryliodonium salts of perfluoro-octanesulfonic acid, and diaryliodonium salts of trifluoromethane sulfonic acid. Preferred diaryliodonium salts of aryl sulfonic acids include diaryliodonium salts of para-toluene sulfonic acid, diaryliodonium salts of dodecylbenzene sulfonic acid, diaryliodonium salts of benzene sulfonic acid, and diaryliodonium salts of 3-nitrobenzene sulfonic acid. Preferred triarylsulfonium salts of sulfonic acid are selected from triarylsulfonium salts of perfluoroalkylsulfonic acids or triarylsulfonium salts of aryl sulfonic acids. Preferred triarylsulfonium salts of perfluoroalkylsulfonic acids include triarylsulfonium salts of perfluorobutanesulfonic acid, triarylsulfonium salts of perfluoroethanesulfonic acid, triarylsulfonium salts of perfluoro-octanesulfonic acid, and triarylsulfonium salts of trifluoromethane sulfonic acid. Preferred triarylsulfonium salts of ay sulfonic acids include triarylsulfonium salts of para-toluene sulfonic acid, triarylsulfonium salts of dodecylbenzene sulfonic acid, triarylsulfonium salts of benzene sulfonic acid, and triarylsulfonium salts of 3-nitrobenzene sulfonic acid. Preferred diaryliodonium salts of boronic acids include diaryliodonium salts of perhaloarylboronic acids and preferred triarylsulfonium salts of boronic acids are the triarylsulfonium salts of perhaloarylboronic acid. The initiators (II) may be present in any proportions which effect curing in the compositions of this invention. Preferably the amount of initiator is from 0.1 to 10 weight percent based on the total weight of the composition, and it is highly preferred to use between 1 and 5 weight percent based on the total weight of the radiation curable silicone coating composition.

The radiation curable silicone coatings can further contain optional ingredients such as photosensitizers, fillers, high release additives, reactive diluents such as organic vinyl ethers, photochromic materials, dyes, colorants, preservatives, fragrances, and other radiation curable compounds may be included in the composition. Preferably no more than 25 parts by weight of the composition is occupied by optional ingredients. While commonly known carbonyl-containing aromatic compounds can be used as the optional photosensitizer, there are no particular limitations concerning these compounds so long as they produce photosensitizing effects. Examples of photosensitizers can include, for example, isopropyl-9H-thioxanthene-9-one, anthrone, 1-hydroxycyclohexyl-phenylketone, and 2-hydroxy-2-methyl-1-phenylpropan-1-one.

The curable silicone composition can be a hydrosilylation curable composition comprising: (A) an organopolysiloxane containing an average of at least two silicon-bonded alkenyl groups per molecule, (B) an organosilicon compound containing an average of at least two silicon-bonded hydrogen atoms per molecule in a concentration sufficient to cure the composition, and (C) a catalytic amount of a photoactivated hydrosilylation catalyst.

Component (A) is at least one organopolysiloxane containing an average of at least two silicon-bonded alkenyl groups per molecule. The organopolysiloxane can have a linear, branched, or resinous structure. The organopolysiloxane can be a homopolymer or a copolymer. The alkenyl groups typically have from 2 to about 10 carbon atoms, alternatively from 2 to 6 5 carbon atoms. Examples of alkenyl groups include, but are not limited to, vinyl, allyl, butenyl, and hexenyl. The alkenyl groups in the organopolysiloxane can be located at terminal, pendant, or both terminal and pendant positions. The remaining silicon-bonded organic groups in the organopolysiloxane are independently selected from hydrocarbyl, deuterium-substituted hydrocarbyl, and halogen-substituted hydrocarbyl, all free of aliphatic unsaturation. As used 10 herein, the term “free of aliphatic unsaturation” means the groups do not contain an aliphatic carbon-carbon double bond or carbon-carbon triple bond. These monovalent groups typically have from 1 to about 20 carbon atoms, alternatively from 1 to 10 carbon atoms. Acyclic monovalent groups containing at least 3 carbon atoms can have a branched or unbranched structure. Examples of hydrocarbyl groups include, but are not limited to, alkyl, such as methyl, ethyl, propyl, 1-methylethyl, butyl, 1-methylpropyl, 2-methylpropyl, 1, 1-dimethylethyl, pentyl, 1-methylbutyl, I-ethylpropyl, 2-methylbutyl, 3-methylbutyl, 1,2-dimethylpropyl, 2,2-dimethylpropyl, hexyl, heptyl, octyl, nonyl, decyl, undecyl, dodecyl, tridecyl, tetradecyl, pentadecyl, hexadecyl, heptadecyl, and octadecyl; cycloalkyl, such as cyclopentyl, cyclohexyl, 20 and methylcyclohexyl; aryl, such as phenyl and naphthyl; alkaryl, such as tolyl and xylyl; and aralkyl, such as benzyl and phenethyl. Examples of deuterium-substituted hydrocarbyl groups include, but are not limited to, the hydrocarbyl groups listed above wherein at least one deuterium atom replaces an equal number of hydrogen atoms. Examples of halogen-substituted hydrocarbyl groups include, but are not limited to, 3,3,3-trifluoropropyl, 3-chloropropyl, 25 dichlorophenyl, dibromophenyl, and 3,4,5,6-nonafluorohexyl. The viscosity of the organopolysiloxane at 25° C., which varies with molecular weight and structure, is typically from 0.001 to 100,000 Pa·s, alternatively from 0.01 to 10,000 Pa·s, alternatively from 0.01 to 10,000 Pa·s.

Organopolysiloxanes useful as (A) in the hydrosilylation curable silicone composition include, but are not limited to, alkenyl containing polydiorganosiloxane polymers and alkenyl containing organopolysiloxane resins. Examples of polydiorganosiloxane polymers include those having the following formulae: ViMe₂SiO(Me₂SiO)ₐSiMe₂Vi, ViMe₂SiO(MeViSiO)ₐSiMe₂Vi, Me₃SiO(Me_{Vi}SiO)ₐSiMe₃, and PhMeViSiO(Me₂SiO)ₐSiPhMeVi, where Me, Vi, and Ph denote methyl, vinyl, and phenyl respectively and a has a value such that the viscosity of the polydiorganosiloxane is from 0.001 to 100,000 Pa·s at 2S ° C.

Methods of preparing polydiorganosiloxanes suitable for use in the silicone composition, such as hydrolysis and condensation of the corresponding organohalosilanes or 10 equilibration of cyclic polydiorganosiloxanes, are well known in the art.

Component (A) can be a single organopolysiloxane or a mixture comprising two or more organopolysiloxanes that differ in at least one of the following properties: structure, viscosity, average molecular weight, siloxane units, and sequence.

Component (B) is at least one organosilicon compound containing an average of at least two silicon-bonded hydrogen atoms per molecule. It is generally understood that crosslinking occurs when the sum of the average number of alkenyl groups per molecule in component (A) and the average number of silicon-bonded hydrogen atoms per molecule in component (B) is greater than four. The silicon-bonded hydrogen atoms in the organohydrogenpolysiloxane can be located at terminal, pendant, or at both terminal and pendant positions. The organosilicon compound can be an organosilane or an organohydrogensiloxane. The organosilane can be a monosilane, disilane, trisilane, or polysilane. Similarly, the organohydrogensiloxane can be a disiloxane, trisiloxane, or polysiloxane. Preferably, the organosilicon compound is an organohydrogensiloxane and more preferably, the organosilicon compound is an organohydrogenpolysiloxane. The structure of the organosilicon compound can be linear, branched, cyclic, or resinous. Typically, at least 50 percent of the organic groups in the organosilicon compound are methyl.

Examples of polysiloxanes such as a trimethylsiloxy-terminated poly(methylhydrogensiloxane), a trimethylsiloxy-terminated poly (dimethylsiloxane/methylhydrogensiloxane), and a dimethylhydrogensiloxy-terminated poly(methylhydrogensiloxane).

Component (B) can be a single organosilicon compound or a mixture comprising two or more such compounds that differ in at least one of the following properties: structure, average molecular weight, viscosity, silane units, siloxane units, and\sequence.

The concentration of component (B) in the silicone composition of the present invention is sufficient to cure (crosslink) the composition. The exact amount of component (B) depends on the desired extent of cure, which generally increases as the ratio of the number of moles of silicon-bonded hydrogen atoms in component (B) to the number of moles of alkenyl groups in component (A) increases. The concentration of component (B) is typically sufficient to provide from 0.5 to 3 silicon-bonded hydrogen atoms, alternatively from 0.7 to 1.2 silicon-bonded hydrogen atoms, per alkenyl group in component (A).

Methods of preparing organosilicon compounds containing silicon-bonded hydrogen atoms are well known in the art. For example, organopolysilanes can be prepared by reaction of chlorosilanes in a hydrocarbon solvent in the presence of sodium or lithium metal (Wurtz reaction). Organopolysiloxanes can be prepared by hydrolysis and condensation of organohalosilanes.

Component (C) is a photoactivated hydrosilylation catalyst. The photoactivated hydrosilylation catalyst can be any hydrosilylation catalyst capable of catalyzing the hydrosilylation of component (A) with component (B) upon exposure to radiation having a wavelength of from 150 to 800 nm and subsequent heating. The platinum group metals include platinum, rhodium, ruthenium, palladium, osmium and iridium. Preferably, the platinum group metal is platinum, based on its high activity in hydrosilylation reactions. The suitability of particular photo activated hydrosilylation catalyst for use in the silicone composition of the present invention can be readily determined by routine experimentation.

Examples of photoactivated hydrosilylation catalysts include, but are not limited to platinum(II) β-diketonate complexes such as platinum(II) bis(2,4-pentanedioate), platinum(II) bis(2,4-hexanedioate), platinum(II) bis(2,4-heptanedioate), platinum(II) bis(1-phenyl-1,3-butanedioate, platinum(II) bis(1,3-diphenyl-1,3-propanedioate), platinum(II) bis (1,1,1,5,5,5-hexafluoro-2,4-pentanedioate); (n-cyclopentadienyl)trialkylplatinum complexes such as (Cp)trimethylplatinum, (Cp)ethyldimethylplatinum, (Cp)triethylplatinum, (chloro-Cp)trimethylplatinum, and (trimethylsilyl-Cp)trimethylplatinum, where Cp represents cyclopentadienyl, triazene oxide-transition metal complexes, and (aryl)platinum complexes. Component (C) can be a single photoactivated hydrosilylation catalyst or a mixture comprising two or more such catalysts. The concentration of component (C) is sufficient to catalyze the addition reaction of components (A) and (B) upon exposure to radiation and heat in the method described below. The concentration of component (C) is typically sufficient to provide from 0.1 to 1000 ppm of 10 platinum group metal, alternatively from 0.5 to 100 ppm of platinum group metal, alternatively from 1 to 25 ppm of platinum group metal, based on the combined weight of components (A), (B), and (C). The rate of cure is very slow below 1 ppm of platinum group metal. The use of more than 100 ppm of platinum group metal results in no appreciable increase in cure rate, and is therefore uneconomical.

Methods of preparing the preceding photoactivated hydrosilylation catalysts are well known in the art. Mixtures of the aforementioned components (A), (B), and (C) may begin to cure at ambient temperature.

To obtain a longer working time or “pot life”, the activity of the catalyst under ambient conditions can be retarded or suppressed by the addition of a suitable inhibitor to 25 the silicone composition of the present invention. A platinum catalyst inhibitor retards curing of the present silicone composition at ambient temperature, but does not prevent the composition from curing at elevated temperatures. Suitable platinum catalyst inhibitors include various “eneyne” systems such as 3-methyl-3-penten-1-yne and 3,5-dimethyl-3-hexen-1-yne; acetylenic alcohols such as 3,5-dimethyl-1-hexyn-3-ol, 1-ethynyl-1-cyclohexanol, and 2-phenyl-3-butyn-2-ol; maleates and fumarates, such as the well known dialkyl, dialkenyl, and dialkoxyalkyl fumarates and maleates; and cyclovinylsiloxanes. Acetylenic alcohols constitute a preferred class of inhibitors in the silicone composition of the present invention. The concentration of platinum catalyst inhibitor in the present silicone composition is sufficient to retard curing of the composition at ambient temperature without preventing or excessively prolonging cure at elevated temperatures. This concentration will vary widely depending on the particular inhibitor used, the nature and concentration of the hydrosilylation catalyst, and the nature of the organohydrogenpolysiloxane. Inhibitor concentrations as low as one mole of inhibitor per mole of platinum group metal will in some instances yield a satisfactory storage stability and cure rate. In other instances, inhibitor concentrations of up to 500 or more moles of inhibitor per mole of platinum group metal may be required. The optimum concentration for a particular inhibitor in a given silicone composition can be readily determined by routine experimentation.

The silicone composition can also comprise additional ingredients, provided the ingredient does not adversely affect the photopatterning or cure of the composition in the method of the present invention. Examples of additional ingredients include, but are not limited to, adhesion promoters, solvents, inorganic fillers, photo sensitizers, and surfactants. The silicone composition can further comprise an appropriate quantity of at least one organic solvent to lower the viscosity of the composition and facilitate the preparation, handling, and application of the composition. Examples of suitable solvents include, but are not limited to, saturated hydrocarbons having from 1 to about 20 carbon atoms; aromatic hydrocarbons such as xylenes and mesitylene; mineral spirits; halo hydrocarbons; esters; ketones; silicone fluids such as linear, branched, and cyclic polydimethylsiloxanes; and mixtures of such solvents. The optimum concentration of a particular solvent in the present silicone composition can be readily determined by routine experimentation.

The silicone composition can be a one-part composition comprising components (A) through (C) in a single part or, alternatively, a multi-part composition comprising components (A) through (C) in two or more parts. In a multi-part composition, components (A), (B), and (C) are typically not present in the same part unless an inhibitor is also present. For example, a multi-part silicone composition can comprise a first part containing a portion of component (A) and a portion of component (B) and a second part containing the remaining portion of component (A) and all of component (C). The one-part silicone composition is typically prepared by combining components (A) through (C) and any optional ingredients in the stated proportions at ambient temperature with or without the aid of a solvent, which is described above. Although the order of addition of the various components is not critical if the silicone composition is to be used immediately, the hydrosilylation catalyst is typically added last at a temperature below about 30° C. to prevent premature curing of the composition. Also, the multi-part silicone composition can be prepared by combining the particular components designated for each part.

The substrate can be a rigid or flexible material. Examples of substrates include, but are not limited to, a semiconductor material such as silicon, silicon having a surface layer of silicon dioxide, and gallium arsenide; quartz; fused quartz; aluminum oxide; polyolefins such as 30 polyethylene and polypropylene; fluorocarbon polymers such as polytetrafluoroethylene and polyvinyl fluoride; polystyrene; polyamides such as Nylon; polyimides; polyesters and acrylic polymers such as poly(methyl methacrylate); epoxy resins; polycarbonates; polysulfones; polyether sulfones; ceramics; and glass.

The curable silicone composition can be applied to the substrate using any conventional method, such as spin coating, dipping, spraying, brushing, or screen printing. The curable silicone composition is typically applied by spin coating at a speed of from 200 to 5000 rpm for 5 to 60 s. The spin speed, spin time, and viscosity of the curable silicone composition can be adjusted so that the lower clad layer produced in step (ii) has the desired thickness.

Step (ii) in the method of this invention comprises exposing the product of step (i) to ultraviolet light to form a lower clad layer. The product of step (i) is exposed to ultraviolet light having a wavelength of from 150 to 450 nm, alternatively from 250 to 450 nm. The light source typically used is a high pressure mercury-arc lamp. The dose of radiation is typically from 0.1 to 5,000 mJ/cm², alternatively from 250 to 1,300 mJ/cm².

Step (iii) comprises applying a photo sensitive composition on top of the lower clad layer to form a core layer on top of the lower clad layer, wherein the photo sensitive composition comprises components (A), (B), and (C) as described above.

In the siloxane resin composition (A), R¹ is hydrogen, an alkyl group containing 1 to 20 carbon atoms, an aromatic group containing 1 to 20 carbon atoms or an epoxy functional group as described above. The alkyl group containing 1 to 20 carbon atoms is exemplified by alkyl groups such as methyl, ethyl, propyl, butyl, hexyl, octyl, and decyl, or cycloaliphatic radicals such as cyclohexyl. The aromatic group containing 1 to 20 carbon atoms is exemplified by phenyl, tolyl, and xylyl, or aralkyl groups such as benzyl and phenylethyl. Alternatively R¹ is selected from methyl, phenyl, hydrogen, an epoxy functional group as described above, or mixtures thereof.

In the siloxane resin composition (A), R² is a fluoroalkyl group containing 1 to 20 carbon atoms which is exemplified by fluoroalkyl groups having the formula —(CH₂)ₘCF₃, and —(CH₂)ₘ(CF₂)ₙCF₃, where m has a value of from 1 to 19, and n has a value of from 1 to 18, wherein the total value of m+n is from 1 to 19. The fluoroalkyl group R² is exemplified by —(CH₂)₂CF₃ and —(CH₂)₂(CF₂)₅CF₃.

In the siloxane resin composition (A), R³ is a substituted or unsubstituted branched alkyl group having 3 to 30 carbon atoms. The substituted branched alkyl group can be substituted with substituents in place of a carbon bonded hydrogen atom (C—H). Substituted R³ groups are exemplified by, but not limited to, halogen such as chlorine and fluorine, alkoxycarbonyl such as described by formula —(CH₂)ₐC(O)O(CH₂)_{b}CH₃, alkoxy substitution such as described by formula —(CH₂)ₐO(CH₂)_{b}CH₃, and carbonyl substitution such as described by formula —(CH₂)ₐC(O)(CH₂)_{b}CH₃, where a and b are both greater than or equal to zero. Unsubstituted R³ groups are exemplified by, but not limited to, isopropyl, isobutyl, sec-butyl, tert-butyl, isopentyl, neopentyl, tert-pentyl, 2-methylbutyl, 2-methylpentyl, 2-methylhexyl, 2-ethylbutyl, 2-ethylpentyl, and 2-ethylhexyl. Alternatively R³ is a tertiary alkyl group having 4 to 18 carbon atoms including where R³ is tertiary (tert) butyl group.

In other embodiments the siloxane resin composition (A) can contain 5 to 95 mole percent of R¹SiO_{3/2} siloxane units, 5 to 95 mole percent of R²SiO_{3/2} siloxane units, and 1 to 99.9 mole percent of (R³O)_{b}SiO_{(4-b)/2} siloxane units.

The structure of the siloxane resin is not specifically limited. The siloxane resins may be essentially fully condensed or may be only partially reacted (i.e., containing less than 10 mole % Si—OR and/or less than 30 mole % Si—OH). The partially reacted siloxane resins may be exemplified by, but not limited to, siloxane units such as R¹Si(X)_{d}O_{(3-d/2)}, R²Si(X)_{d}O_{(3-d/2)}, and Si(X)_{d}(OR³)_{f}O_{(4-d-f/2)}, in which R¹, R², and R³ are defined above; each X is independently a hydrolyzable group or a hydroxy group, and d and f are from 1 to 2. The hydrolyzable group is an organic group attached to a silicon atom through an oxygen atom (Si—OR) forming a silicon bonded alkoxy group or a silicon bonded acyloxy group. R is exemplified by, but not limited to, linear alkyl groups having 1 to 6 carbon atoms such as methyl, ethyl, propyl, butyl, pentyl, or hexyl and acyl groups having 1 to 6 carbon atoms such as formyl, acetyl, propionyl, butyryl, valeryl or hexanoyl. The siloxane resin may also contain less than about 10 mole percent SiO_{4/2} units.

The siloxane resins have a weight average molecular weight in a range of 400 to 160,000 and alternatively in a range of 5,000 to 100,000.

The photo acid generator (PAG), ingredient (B) is a compound that generates acid upon exposure to radiation. This acid then causes the acid dissociable group in the silsesquioxane resin to dissociate. Acid generators are well known in the art and are described in, for example, EP1142928 A1. Acid generators may be exemplified by, but not limited to, onium salts, halogen-containing compounds, diazoketone compounds, sulfone compounds, sulfonate compounds and others. Examples of onium salts include, but are not limited to, iodonium salts, sulfonium salts (including tetrahydrothiophenium salts), phosphonium salts, diazonium salts, and pyridinium salts.

Photo-acid generators may be exemplified by, but not limited to, onium salts, halogen-containing compounds, diazoketone compounds, sulfone compounds, sulfonate compounds and others. Examples of onium salts include, but are not limited to, iodonium salts, sulfonium salts (including tetrahydrothiophenium salts), phosphonium salts, diazonium salts, and pyridinium salts. Examples of halogen-containing compounds include, but are not limited to, mahaloalkyl group-containing hydrocarbon compounds, haloalkyl group-containing heterocyclic compounds, and others. Examples of diazoketone compounds include, but are not limited to, 1,3-diketo-2-diazo compounds, diazobenzoquinone compounds, diazonaphthoquinone compounds, and others. Examples of sulfone compounds, include, but are not limited to, .beta.-ketosulfone, .beta.-sulfonylsulfone, .alpha.-diazo compounds of these compounds, and others. Examples of sulfonate compounds include, but are not limited to, alkyl sulfonate, alkylimide sulfonate, haloalkyl sulfonate, aryl sulfonate, imino sulfonate, and others. The photo-acid generator (B) may be used either individually or in combination of two or more. The preferred acid generators are sulfonated salts, in particular sulfonated salts with perfluorinated methide anions. The amount of (B) in the photo sensitive composition is typically in the range of 0.1 to 8 parts by weight based on 100 parts of (A), the siloxane resin composition, and alternatively 0.42 to 35 parts by weight based on 100 parts of (A).

Component (C) in the composition is an organic solvent. The choice of solvent is governed by many factors such as the solubility and miscibility of the siloxane resin composition and photo-acid generator, the coating process and safety and environmental regulations. Typical solvents include ether-, ester-, hydroxyl-fluorinated hydrocarbons and ketone-containing compounds, and mixtures thereof. Examples of solvents include, but are not limited to, cyclopentanone, cyclohexanone, lactate esters such as ethyl lactate, alkylene glycol alkyl ethers such as ethylene glycol methyl ether, dialkylene glycol dialkyl ethers such as diethylene glycol dimethyl ether, alkylene glycol alkyl ether esters such as propylene glycol methyl ether acetate, alkylene glycol ether esters such as ethylene glycol ether acetate, alkylene glycol monoalkyl esters such as methyl cellosolve, butyl acetate, 2-ethoxyethanol, trifluoromethylbenzene and ethyl 3-ethoxypropionate. Typically, solvents for silsesquioxane resins include, but are not limited to cyclopentanone (CP), propylene glycol methyl ether acetate (PGMEA), ethyl lactate (EL), methyl isobutyl ketone (MIBK), methyl ethyl ketone (MEK), ethyl 3-tethoxypropionate, 2-heptanone or methyl n-amyl ketone (MAK), and/or any their mixtures. The amount of solvent is typically present at 10 to 95 wt % of the total composition (i.e. (A), (B), and (C), alternatively, 30 to 60 wt % of the total composition.

Additives (D) may be optionally used in the photo sensitive composition. For example, if the photo sensitive composition is used as a positive photoresist, then the composition may include photo sensitizer, acid-diffusion controllers, surfactants, dissolution inhibitors, cross-linking agents, sensitizers, halation inhibitors, adhesion promoters, storage stabilizers, anti-foaming agents, coating aids, plasticizers, among others. The additive would be similar for both the positive and negative resist. An example of photo sensitizer is ITX (Isopropylthioxanthone). Typically, the sum of all additives (not including the acid generator) will comprise less than 10 percent of the solids included in the photoresist composition, alternatively less than 5 percent.

Step (iv) in the method of this invention comprises exposing the product of step (iii) to ultraviolet light through a mask to selectively irradiate the core layer to create both exposed and unexposed regions to form a patterned waveguide structure.

The product of step (i) is exposed to ultraviolet light having a wavelength of from 150 to 450 nm, alternatively from 250 to 450 nm. The light source typically used is a high pressure mercury-arc lamp. The dose of radiation is typically from 0.1 to 5,000 mJ/cm², alternatively from 250 to 1,300 mJ/cm².

The mask is a photomask having a pattern of images and the mask can be a negative photoresist mask or a positive photoresist mask.

Step (v) comprises heating the patterned waveguide structure of step (iv). The patterned waveguide can be heated at a temperature of from about 50° C. to about 250° C. for about 0.1 minutes to about 10 minutes, alternatively from about 100° C. to about 200° C. for about 1 minute to about 5 minutes, alternatively from about 135° C. to about 165° C. for about 2 minutes to about 4 minutes. The patterned waveguide can be heated using conventional equipment such as a hot plate or an oven.

Step (vi) comprises applying a developing solvent to the product of step (v). The non-exposed region of step (iv) can be removed with a developing solvent to form a patterned film. The developing solvent can include an organic solvent in which the non-exposed region is at least partially soluble and the exposed region is substantially insoluble. The developing solvent can have from 3 to 20 carbon atoms per molecule. Examples of developing solvents include ketones, such as methyl isobutyl ketone and methyl pentyl ketone; ethers, such as n-butyl ether and polyethylene glycol monomethylether; esters, such as ethyl acetate and γ-butyrolactone; aliphatic hydrocarbons, such as nonane, decalin, and dodecane; and aromatic hydrocarbons, such as mesitylene, xylene, and toluene. The developing solvent can be applied by any conventional method, including spraying, immersion, and pooling. For example, the developing solvent can be applied by forming a pool of the solvent on a stationary substrate and then spin-drying the substrate. The developing solvent can be used at a temperature of from room temperature to 100° C. The specific temperature of use depends on, for example, the chemical properties of the solvent, the boiling point of the solvent, the desired rate of pattern formation, and the requisite resolution of the photopatterning process. When the mask used is as a positive photoresist mask, the exposed resin become more soluble and the unexposed resin crosslinked to some extent during the heating process and become insoluble.

Step (vii) comprises applying a curable silicone composition onto the top layer of the product of step (vi) wherein the curable silicone composition has a lower refractive index than the curable silicone composition of step (i). The second curable silicone composition can be any curable silicone composition having a refractive index less than the refractive index of the curable silicone composition of step (i). The second curable silicone composition is as described and exemplified above for the curable silicone composition of step (i). The curable silicone composition can be applied to the substrate using any conventional method, such as spin coating, dipping, spraying, brushing, or screen printing. The curable silicone composition is typically applied by spin coating at a speed of from 200 to 5000 rpm for 5 to 60 s. The spin speed, spin time, and viscosity of the curable silicone composition can be adjusted so that the lower clad layer produced in step (ii) has the desired thickness. The curable silicone composition of step (vi) has a refractive index less than the refractive index of the curable silicone composition of step (i). The magnitude of the difference in refractive index between the two depends on several factors, including the thickness of the core, wavelength of propagated light, and mode of wave propagation (i.e., single mode or multimode). The difference in refractive index between the two curable silicone compositions can be from about 0.0005 to about 0.5, alternatively from about 0.001 to about 0.05, alternatively from about 0.005 to about 0.02.

Step (viii) of the method of this invention comprises exposing the product of step (vii) to ultraviolet light. The product of step (viii) is exposed to ultraviolet light having a wavelength of from 150 to 450 nm, alternatively from 250 to 450 nm. The light source typically used is a medium pressure mercury-arc lamp. The dose of radiation is typically from 0.1 to 5,000 mJ/cm2, alternatively from 250 to 1,300 mJ/cm2 and is typically exposed for 0.001 to 250 seconds.

Step (viv) of the method of this invention comprises heating the product of step (viii) to form a planar optical waveguide assembly. The patterned waveguide can be heated at a temperature of from about 50° C. to about 250° C. for about 0.1 minutes to about 10 minutes, alternatively from about 100° C. to about 200° C. for about 1 minute to about 5 minutes, alternatively from about 135° C. to about 165° C. for about 2 minutes to about 4 minutes. The patterned waveguide can be heated using conventional equipment such as a hot plate or an oven.

The method of this invention can further comprise irradiating the product of step (vi) with a low dose of ultraviolet light prior to step (vii). The low dose of ultraviolet light is typically from a wavelength of from 150 to 450 nm, alternatively from 250 to 450 nm. The light source typically used is a medium pressure mercury-arc lamp. The dose of radiation is typically from 0.1 to 5,000 mJ/cm2, alternatively from 250 to 1,300 mJ/cm2 and is typically exposed for 0.001 to 250 seconds.

The method of this invention can further comprise heating the product of steps (ii), (iii), and/or (vi). When the silicone composition comprises a solvent, the method can further comprise removing at least a portion of the solvent from the silicone film. The solvent can be removed by heating the silicone film at a temperature of from 50 to 150° C. for 1 to 5 minutes, alternatively from 80 to 120° C. for 2 to 4 minutes.

### EXAMPLES

Resins with a (R¹SiO_{3/2})ₓ(R²SiO_{3/2})_{y}(R³OSiO_{3/2})z composition were synthesized by hydrolysis and condensation of (AcO)₂Si(OtBu)₂, R¹Si(OMe)₃ and R²Si(OMe)₃, R¹ is phenyl; R² is —CH₂CH₂CF₃ or R² is —CH₂CH₂(CF₂)₅CF₃, R³ is a tert butyl group (t-Bu). The reactions were carried out in toluene solution catalyzed using acetic acid generated in situ. The following non-limiting examples are provided so that one skilled in the art may more readily understand the invention. In the Examples weights are expressed as grams (g). Molecular weight is reported as weight average molecular weight (M_{w}) and number average molecular weight (Mₙ) determined by Gel Permeation Chromatography. Analysis of the siloxane resin composition was done using ²⁹Si and ¹³C nuclear magnetic resonance (NMR).

### Example 1 (Synthesis of Resin for Core 1 Formulation)

This example illustrates the formation of a siloxane resin compositions where R¹ is phenyl, R² is —CH₂CH₂CF₃, R³ is a tert-butyl group. Samples of 80.0 g of PhSi(OMe)₃, 44.4 g of R²Si(OMe)₃, were mixed with 130 g of toluene in a three neck flask equipped with a mechanical stir, a thermal couple and addition funnel under a nitrogen atmosphere. Deionized water (37.3 g) was then added to the flask, 117.2 g of (AcO)₂Si(OtBu)₂ was then added dropwise into the mixture. The temperature rose to 37° C. after addition of (AcO)₂Si(OtBu)₂. The mixture was then heated to 59° C. and stirred at for 1 hour. The solvent was removed using a rotary evaporator at 50° C. under reduced pressure (0-2 mTorr) to yield a siloxane resin as a viscous oil, which was immediately dissolved into 100 g of toluene. The volatile materials were evaporated using a rotary evaporator at the same conditions. The same process was repeated with another 100 g of toluene to remove residual acetic acid. The resin was then dissolved into 300 g of toluene, charged into a three neck flask equipped with a mechanical stir, a thermal couple, and heated in refluxing toluene at 107° C. to continuously remove water using a dean-stark condenser for 30 minutes. The solution was cooled to room temperature and filtered to yield a resin product with 51.8% solid in toluene. GPC analyses of the product show M_{w}: 9140 and Mₙ: 3490. ²⁹SiNMR and ¹³C NMR analyses show a composition of(PhSiO_{3/2})_{0.44}(CF₃CH₂CH₂SiO_{3/2})_{0.20}(t-BuOSiO_{3/2})_{0.36}

### Example 2 (Synthesis of Resin for Clad 1 Formulation)

The reaction was carried out using a three-neck round bottom flask that was fitted with an addition funnel, a mechanical stirring rod and Dean-Stark trap connected with a condenser. The reactor was first purged with nitrogen for 30 minutes and then loaded with 272.1 g R¹Si(OMe)₃ wherein R¹ denotes —CH₂CH₂CF₃, 222.0 g of R²Si(OMe)₃ wherein R² denotes (2-(3,4 epoxycyclohexyl)ethyl (i.e. —CH₂CH₂C₆H₉O) (KBM 303 (2-(3,4 epoxycyclohexyl)ethyl trimethoxysilane from Shin E'tsu Chemical), 49.7 g of Me₃Si(OMe) and 292 g of toluene. The reaction mixture was heated to 41° C. Then 1.88 g of 30% KOH aqueous solution was added while stirring. The heat was then removed by unplugging the heating mantle. A 92.9 g of water was added drop-wise, while maintaining pot temperature between 43 and 63° C. through control of addition rate. After the water addition, the reaction mixture was heated to the reflux temperature (66° C.) and volatile materials collected from 66° C. to 69° C. When the pot temperature reached 69° C., 144 g of toluene was added. The reaction mixture was continued to be heated and distillate removed via distillation (total 461 g). The pot temperature was maintained for 1.5 hours to remove residual water using a Dean-Stark condenser at 114° C. The solution was then cooled to 60° C., and a solution of 9.38 g of acetic acid in toluene (10%) was added. The solution was re-heated to reflux temperature (115° C.) and held for 30 minutes. Additional 66 g of volatile material was collected. The reaction mixture was then cooled to room temperature, and filtered through 0.45 micron membrane filter to yield a solution with 69.8% resin. GPC analyses of the product show M_{w}: 31,100 and Mₙ: 1,690. ²⁹Si NMR analyses show a composition of (OC₆H₉CH₂CH₂SiO_{3/2}+CF₃CH₂CH₂SiO_{3/2})_{0.87}(Me₃SiO_{1/2})_{0.13}

### Example 3 (Synthesis of Resin for Core 2 Formulation)

This example illustrates the formation of a siloxane resin compositions where R¹ is phenyl, R² is —CH₂CH₂(CF₂)₅CF₃, R³ is a t-butyl group. Samples of 49.6 g of PhSi(OMe)₃, 140.5 g of R²Si(OMe)₃, were mixed with 133 g of toluene in a three neck flask equipped with a mechanical stir, a thermal couple and addition funnel under an argon atmosphere. Deionized water (37.3 g) was then added all together to the flask, 131.6 g of (AcO)₂Si(OtBu)₂ was then added dropwise into the mixture. The temperature rose to 32° C. after addition. The mixture was then heated to 71° C. and stirred at for 1 hour. The solvent was removed using a rotary evaporator at 50° C. under reduced pressure (0-2 mTorr) to yield a siloxane resin as a viscous oil, which was immediately dissolved into 150 g of toluene. The volatile materials were evaporated using a rotary evaporator at the same conditions. The same process was repeated with another 150 g of toluene to remove residual acetic acid. The resin was then dissolved into 300 g of toluene, charged into a three neck flask equipped with a mechanical stir, a thermal couple, heated in refluxing toluene at 110° C. to continuously remove water using a dean-stark condenser for 30 minutes. The resin phase separated from toluene after cooling to room temperature. Volatile materials were removed using a rotary evaporator at 50° C. The resin was then dissolved in 110 g of trifluoro toluene. The solution was filtered to produce the final siloxane resin product with 53.3% solid in toluene. ²⁹Si and ¹³C NMR analysis show a composition of (PhSiO_{3/2})_{0.21}(CF₃(CF₂)₅CH₂CH₂SiO_{3/2})_{0.27}(t-BuOSiO_{3/2})_{0.52}

### Example 4 (Synthesis of Resin for Clad 2 Formulation)

This example illustrates the formation of a siloxane resin compositions where R¹ is phenyl, R² is —CH₂CH₂(CF₂)₅CF₃, R³ is a t-butyl group. Samples of 49.6 g of PhSi(OMe)₃, 163.9 g of R²Si(OMe)₃, were mixed with 133 g of toluene in a three neck flask equipped with a mechanical stir, a thermal couple and addition funnel under an argon atmosphere. Deionized water (37.3 g) was then added all together to the flask, 117.2 g of (AcO)₂Si(OtBu)₂ was then added dropwise into the mixture. The temperature rose to 34° C. after addition. The mixture was then heated to 73° C. and stirred at for 1 hour. The solvent was removed using a rotary evaporator at 50° C. under reduced pressure (0-2 mTorr) to yield a siloxane resin as a viscous oil, which was immediately dissolved into 150 g of toluene. The volatile materials were evaporated using a rotary evaporator at the same conditions. The same process was repeated with another 150 g of toluene to remove residual acetic acid. The resin was then dissolved into 300 g of toluene, charged into a three neck flask equipped with a mechanical stir, a thermal couple, heated in refluxing toluene at 108° C. to continuously remove water using a dean-stark condenser for 30 minutes. The resin phase separated from toluene after cooling to room temperature. Volatile materials were removed using a rotary evaporator at 50° C. The resin was then dissolved in 110 g of trifluoro toluene. The solution was filtered to produce the final siloxane resin product with 56.6% solid in toluene. ²⁹SiNMR analysis show a composition of (PhSiO_{3/2})_{0.25}(CF₃(CF₂)₅CH₂CH₂SiO_{3/2})_{0.29}(t-BuOSiO_{3/2})_{0.43}

### Example 5. Fabrication of Waveguide

Core 1 Formulation: A 97 g of resin solution (51.8% solid) prepared in Example 1 was mixed with 1.0 g of CPI 300PG (a catalyst from San-Apro Ltd. Kyoto, Japan). The solution was filtered through 0.45 micron meter syringe filter and used for patterning evaluation. The solution was spun coated on a 4″ Si wafer at 1000 rpm for 20 seconds. Film cured with UV light at 1.2 J/cm² and then heated on a hot plate at 110° C. for 2 minute, then heated in an air circulated oven for 30 minutes. Refractive index of the film was measured using Metricon prism coupler at 632.8 nm: 1.4834.

Clad 1 Formulation 1: a 30.4 g of resin solution (55.7% solid) prepared in Example 2 was mixed with 0.153 g of CPI 300PG (a catalyst from San-Apro Ltd. Kyoto, Japan). The solution was filtered through 0.45 micron meter syringe filter and used for patterning evaluation. The solution was spun coated on a 4″ Si wafer at 2000 rpm for 30 seconds. Film cured with UV light at 1.2 J/cm² and then heated in an air circulated oven at 130° C. for 1 hour. Refractive index of the film was measured using Metricon prism coupler at 632.8 nm: 1.4383.

Waveguide Fabrication: Clad 1 Formulation was spin coated at 1000 RPM, 500 RPM/s, for 20 seconds. An 80° C. hot plate bake was then applied for 2 minutes to remove residual solvent. The entire sample was UV irradiated with a blanket cure dose of 1.2 J/cm² using a UVA mercury bulb. After UV irradiation, the sample was hot plate baked at 110° C. for 2 minutes. Core 1 Formulation was spin coated at 1000 RPM, 500 RPM/s, for 20 seconds. An 80° C. hot plate bake was then applied for 2 minutes to remove residual solvent. Contact masked lithography was utilized with a negative resist mask where expected material removal areas are covered by bronze on a soda lime plate. A UV patterning dose of 2.0 J/cm² was applied using a high pressure mercury arc lamp. After UV irradiation, the sample was hot plate baked at 110° C. for 2 minutes. After hot plate baking, the sample was immersed in toluene, to remove the portion of the sample that was not subjected to UV radiation. The Clad 1 Formulation was spin coated at 1000 RPM, 500 RPM/s, for 20 seconds. An 80° C. hot plate bake was then applied for 2 minutes to remove residual solvent. The entire sample was UV irradiated with a blanket cure dose of 1.2 J/cm² using a UVA mercury bulb. After UV irradiation, the sample was hot plate baked at 110° C. for 2 minutes. After fabrication of the waveguide, the samples were diced using a diamond dicing saw into 10 cm lengths. 1 mm cross cuts were taken for optical imaging.

Optical attenuation of the waveguide structures were taken using active optical alignment of a 1310 nm narrow linewidth laser source coupled to a 8 micron single mode fiber with 0.14 numerical aperture. The single mode fiber was actively aligned to the 10 cm waveguide structure and a 62.5 micron multimode 0.27 numerical aperture receive fiber was actively aligned to the output of the waveguide structure to collect the 1310 nm light transmitted through the waveguide. The difference between the baseline optical power without a waveguide present and the optical power with a waveguide present was taken as the insertion loss of the system. The sample was then dicing to 7 cm and 3 cm and the testing was repeated. The linear regression of the losses can be found in FIGURE and are defined as the attenuation of the material at 0.47 dB/cm.

### Example 6. Fabrication of Waveguide

Core 2 Formulation: A 100 g of resin solution (53.3% solid) prepared in Example 3 was mixed with 0.53 g of a photo acid generator composed of 45% PI-7129 ((3-Methylphenyl) ((C12-C13 branched) phenyl) iodonium hexafluoroantimonate from Hampford Research, Inc., Stratford, Conn.), 5% ITX (Isopropylthioxanthone from Aceto) and 50% decanol (from Aldrich). The solution was filtered through 0.45 micronmeter syringe filter and used for patterning evaluation. The solution was spun coated on a 4″ Si wafer at 1000 rpm for 20 seconds. Film cured with UV light at 1.2 J/cm² and then heated in an air circulated oven at 130° C. for 1 hour. Refractive index of the film was measured using Metricon prism coupler at 1310 nm: 1.3921.

Clad 2 Formulation: A 90 g of resin solution (56.6% solid) prepared in Example 4 was mixed with 10 g of trifluoromethylbenzene, 0.51 g of a photo acid generator composed of 45% PI-7129 ((3-Methylphenyl) ((C12-C13 branched) phenyl) iodonium hexafluoroantimonate from Hampford Research, Inc., Stratford, Conn.), 5% ITX (Isopropylthioxanthone from Aceto) and 50% decanol (Vendor: Aldrich). The solution was filtered through 0.45 micronmeter syringe filter and used for patterning evaluation. The solution was spun coated on a 4″ Si wafer at 1000 rpm for 20 seconds. Film cured with UV light at 1.2 J/cm² and then heated in an air circulated oven at 130° C. for 1 hour. Refractive index of the film was measured using Metricon prism coupler at 1310 nm: 1.3873.

Waveguide Fabrication: The Clad 2 Formulation was spin coated on a 6″ Si wafer at 1000 RPM, 500 RPM/s, for 10 seconds. An 80° C. hot plate bake was then applied for 2 minutes to remove residual solvent. The entire sample was UV irradiated with a blanket cure dose of 1.2 J/cm² using a UVA mercury bulb. After UV irradiation, the sample was hot plate baked at 130° C. for 2 minutes. The Core 2 Formulation was spin coated at 1000 RPM, 500 RPM/s, for 10 seconds. An 80° C. hot plate bake was then applied for 2 minutes to remove residual solvent. Contact masked lithography was utilized with a negative resist mask where expected material removal areas are covered by bronze on a soda lime plate. A UV patterning dose of 2.0 J/cm² was applied using a high pressure mercury arc lamp. After UV irradiation, the entire sample was UV irradiated with a blanket cure dose of 300 mJ/cm² using a UVA mercury bulb. After blanket UV irradiation, the sample was hot plate baked at 80° C. for 2 minutes, followed by a hot plate bake at 130° C. for 30 seconds. The sample was then immersed in trifluoromethylbenzene to remove the portion of the sample that was only subjected to low amounts of UV radiation. The Clad 2 Formulation was spin coated at 1000 RPM, 500 RPM/s, for 10 seconds. An 80° C. hot plate bake was then applied for 2 minutes to remove residual solvent. The entire sample was UV irradiated with a blanket cure dose of 1.2 J/cm² using a UVA mercury bulb. After UV irradiation, the sample was hot plate baked at 130° C. for 2 minutes.

After fabrication of the waveguide, the samples were diced using a diamond dicing saw into 10 cm lengths. Optical attenuation of the waveguide structures were taken using active optical alignment of a 1310 nm narrow linewidth laser source coupled to a 8 micron single mode fiber with 0.14 numerical aperture. The single mode fiber was actively aligned to the 10 cm waveguide structure and a 62.5 micron multimode 0.27 numerical aperture receive fiber was actively aligned to the output of the waveguide structure to collect the 1310 nm light transmitted through the waveguide. The difference between the baseline optical power without a waveguide present and the optical power with a waveguide present was taken as the insertion loss of the system. Insertion loss was divided by the length of the waveguide (10 cm) to give an estimation of optical attenuation of the materials. Since the cutback method was not utilized as in the previous example, losses due to coupling between optical element has not been removed, so actual attenuation values potentially could be lower than the stated attenuation of 0.51 dB/cm @ 1310 nm seen in Table 1.

TABLE 1
Insertion loss values for waveguide testing

| | | | Power | Attenuation |
|---|---|---|---|---|
| Channel | Pwaveguide (dB) | Pfiber (dB) | Loss (dB) | (dB/cm) |
| 1 | −25.5 | −20.4 | 5.1 | 0.51 |
| 2 | −26.1 | −20.4 | 5.7 | 0.57 |
| 3 | −24.9 | −20.4 | 4.5 | 0.45 |
| Average | −25.5 | −20.4 | 5.1 | 0.51 |
| Stdev | 0.6 | 0 | 0.6 | 0.06 |

1. A method of preparing a planar optical waveguide assembly comprising the steps of:
(i) applying a curable silicone composition to a surface of a substrate to form a film;
(ii) exposing the product of step (i) to ultraviolet light to form a lower clad layer;
(iii) applying a photo sensitive composition on top of the lower clad layer to form a core layer on top of the lower clad layer, wherein the photo sensitive composition comprises:
(A) a siloxane resin composition comprising 0 to 95 mole present of R¹SiO_{3/2} siloxane units, 0 to 95 mole percent of R²SiO_{3/2} siloxane units, and 1 to 99.9 mole percent of (R³O)_{b}SiO_{(4-b)/2} siloxane units wherein R¹ is hydrogen, an alkyl group containing 1 to 20 carbon atoms, an aromatic group containing 1 to 20 carbon atoms, or an epoxy functional group, R² is a fluoroalkyl group containing 1 to 20 carbon atoms, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 5 mole percent of the total siloxane units in the resin composition;
(B) a photo acid generator (PAG); and
(C) an organic solvent;
(iv) exposing the product of step (iii) to ultraviolet light through a mask to selectively irradiate the core layer to create both exposed and unexposed regions to form a patterned waveguide structure;
(v) heating the patterned waveguide structure of step (iv);
(vi) applying a developing solvent to the product of step (v);
(vii) applying a curable silicone composition onto the top layer of the product of step (vi) wherein the curable silicone composition has a lower refractive index than the curable silicone composition of step (i);
(viii) exposing the product of step (vii) to ultraviolet light;
(viv) heating the product of step (viii) to form a planar optical waveguide assembly.

2. A method according to claim 1, wherein the method further comprises irradiating the product of step (vi) with a low dose of ultraviolet light prior to step (vii).

3. A method according to claim 1, wherein the method further comprises heating the product of steps (ii), (iii), or (vi).

4. A method according to claim 1, wherein the method further comprises heating the product of steps (ii), (iii), and (vi).

5. A method according to claim 1, wherein the curable silicone composition in step (i) is an ultraviolet light curable silicone composition.

6. A method according to claim 1, wherein the substrate is silicon or silicon dioxide.

7. A method according to claim 1, wherein the lower clad layer has a thickness of from 50 to 200 micron meter.

8. A method according to claim 1, wherein the curable silicone composition comprises is an epoxy functional organopolysiloxane resin and an initiator.

9. A method according to claim 1, wherein the siloxane resin (A) further comprises R¹SiO_{3/2} siloxane units wherein R¹ is an epoxy functional group.

10. A method according to claim 9, wherein R¹ is selected from 2,3-epoxypropyl, 3,4-epoxybutyl, 4,5-epoxypentyl, 2-glycidoxyethyl, 3-glycidoxypropyl, 4-glycidoxybutyl, 2-(3,4-epoxycylohexyl)ethyl, 3-(3,4-epoxycylohexyl)propyl, 2-(3,4-epoxy-3-methylcylohexyl)-2-methylethyl, 2-(2,3-epoxycylopentyl)ethyl, or 3-(2,3-epoxycylopentyl)propyl.
